(19) United States
(12) Patent Application Publication
(10) Pub. No.: US 2026/0150395 A1
(43) Pub. Date: May 28, 2026

(54) SEMICONDUCTOR DEVICE

(71) Applicant: Samsung Electronics Co., Ltd., Suwon-si (KR)

(72) Inventors: HYUN-KWAN YU, Suwon-si (KR); DONGSUK SHIN, Suwon-si (KR); YEONDO JUNG, Suwon-si (KR)

(21) Appl. No.: 19/249,330

(22) Filed: Jun. 25, 2025

(30) Foreign Application Priority Data
Nov. 26, 2024 (KR) 10-2024-0171426

(51) Int. Cl. H10D 84/85; H10D 84/01

(52) U.S. Cl. CPC H10D 84/852; H10D 84/0167; H10D 84/017; H10D 84/0184; H10D 84/0186

(57) ABSTRACT

Provided is a semiconductor device including active patterns on a substrate, a first set of semiconductor patterns and a second set of semiconductor patterns spaced apart from each other in a first direction on the active patterns, the first set of semiconductor patterns including a first semiconductor pattern and a second semiconductor pattern vertically spaced apart from each other, an isolation pattern between the first set of semiconductor patterns and the second set of semiconductor patterns, a first gate electrode on the first set of semiconductor patterns, and an inner gate spacer on a sidewall of the isolation pattern, wherein the isolation pattern and the first semiconductor pattern are spaced apart from each other in the first direction, and the inner gate spacer is interposed between the isolation pattern and the first semiconductor pattern.

### CROSS-REFERENCE TO RELATED APPLICATIONS

This U.S. non-provisional patent application claims priority under 35 U.S.C. §119 of Korean Patent Application No. 10-2024-0171426, filed on Nov. 26, 2024, the entire contents of which are hereby incorporated by reference.

### BACKGROUND

The present disclosure herein relates to a semiconductor device and a method for manufacturing the same, and more particularly, to a semiconductor device including a field-effect transistor and a method for manufacturing the same.

Semiconductor devices include an integrated circuit configured with metal oxide semiconductor field-effect transistors (MOSFETs). As the size and design rule of semiconductor devices are reduced, scaling down of MOSFETs is accelerated. The scaling down of MOSFETs may cause deterioration of operation characteristics of semiconductor devices. Therefore, research is being carried out to develop various methods for manufacturing semiconductor devices having excellent performance while overcoming limitations due to high integration of semiconductor devices.

### SUMMARY

The present disclosure provides a semiconductor device with improved reliability and electrical characteristics.

The present disclosure also provides a method for manufacturing a semiconductor device with improved reliability and electrical characteristics.

An embodiment of the inventive concept provides a semiconductor device including active patterns on a substrate, a first set of semiconductor patterns and a second set of semiconductor patterns spaced apart from each other in a first direction on the active patterns, the first set of semiconductor patterns including a first semiconductor pattern and a second semiconductor pattern spaced apart from each other in a second direction perpendicular to the first direction, an isolation pattern between the first set of semiconductor patterns and the second set of semiconductor patterns, a first gate electrode on the first set of semiconductor patterns, and an inner gate spacer on a sidewall of the isolation pattern, wherein the isolation pattern and the first semiconductor pattern are spaced apart from each other in the first direction, the inner gate spacer is interposed between the isolation pattern and the first semiconductor pattern, and in the first direction, the minimum distance between the first semiconductor pattern and the isolation pattern is different from the minimum distance between the first gate electrode and the isolation pattern.

In an embodiment of the inventive concept, a semiconductor device includes active patterns on a substrate, a first set of semiconductor patterns and a second set of semiconductor patterns spaced apart from each other on the active patterns, the first set of semiconductor patterns including a first semiconductor pattern and a second semiconductor pattern vertically spaced apart from each other, an isolation pattern between the first set of semiconductor patterns and the second set of semiconductor patterns, a first gate electrode on the first set of semiconductor patterns, and an inner gate spacer on a sidewall of the isolation pattern, wherein the inner gate spacer includes a first portion between the isolation pattern and the first semiconductor pattern in a plane extending parallel to the substrate, and a second portion between the isolation pattern and the first gate electrode, and a width of the first portion is different from a width of the second portion in a direction extending parallel to the substrate.

In an embodiment of the inventive concept, a semiconductor device includes a substrate including active patterns, a device isolation layer defining the active patterns, a first set of semiconductor patterns and a second set of semiconductor patterns spaced apart from each other in a first direction on the active patterns, the first set of semiconductor patterns including a first semiconductor pattern and a second semiconductor pattern vertically spaced apart from each other in a second direction perpendicular to the first direction, source/drain patterns connected to the first and second set of semiconductor patterns, an isolation pattern between the first set of semiconductor patterns and the second set of semiconductor patterns, a first gate electrode surrounding the first and second semiconductor patterns with respect to a vertical cross sectional view the first set of semiconductor patterns, a second gate electrode on the second set of semiconductor patterns, a gate insulating layer interposed between the first and second gate electrodes and each of the first and second set of semiconductor patterns, an inner gate spacer on a sidewall of the isolation pattern, a gate spacer on a sidewall of the first and second gate electrodes, gate capping patterns on upper surfaces of the first and second gate electrodes, an interlayer insulating layer covering the source/drain pattern and the gate capping patterns, an active contact penetrating the interlayer insulating layer and electrically connected to one of the first source/drain patterns, a gate contact penetrating the gate capping pattern and the interlayer insulating layer and electrically connected to one of the first and second gate electrodes, and a first metal layer on the interlayer insulating layer, the first metal layer including first and second lines electrically connected to the active contact and the gate contact, wherein the isolation pattern and the first semiconductor pattern are spaced apart from each other in the first direction, the inner gate spacer further includes a first inner edge portion between the isolation pattern and an upper portion of the first semiconductor pattern in a plane extending parallel to the substrate, a first inner middle portion between the isolation pattern and a middle portion of the first semiconductor pattern in a plane extending parallel to the substrate, and a second inner edge portion between the isolation pattern and a lower portion of the first semiconductor pattern in a plane extending parallel to the substrate, and in the first direction, a width of the first inner edge portion is different from a width of the first inner middle portion.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view for describing a semiconductor device according to embodiments of the inventive concept;

FIGS. 2A, 2B, and 2C are cross-sectional views taken along line A-A′, line B-B′, and line C-C′ of FIG. 1, respectively;

FIG. 3A is an enlarged view of region M of FIG. 2A according to an embodiment of the inventive concept;

FIG. 3B is an enlarged view of region N of FIG. 3A according to an embodiment of the inventive concept;

FIGS. 4, 5A, and 6 are enlarged views of region M of FIG. 2A according to other embodiments of the inventive concept;

FIG. 5B is enlarged views of region P of FIG. 5A;

FIGS. 7, 8A, 8B, 8C, 9A, 9B, 10A, 10B, 10C, 11A, 12A, 13A, 13B, and 13C are cross-sectional views for describing a method for manufacturing a semiconductor device according to embodiments of the inventive concept;

FIG. 11B is an enlarged view of region M of FIG. 11A;

FIG. 12B is an enlarged view of region M of FIG. 12A; and

FIG. 14 is a diagram for describing a method for manufacturing a semiconductor device according to another embodiment of the inventive concept.

### DETAILED DESCRIPTION

Hereinafter, embodiments according to the inventive concept will be described in detail with reference to the drawings.

Items described in the singular herein may be provided in plural, as can be seen, for example, in the drawings. Thus, the description of a single item that is provided in plural should be understood to be applicable to the remaining plurality of items unless context indicates otherwise.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Throughout the specification, when a component is described as “including” a particular element or group of elements, it is to be understood that the component is formed of only the element or the group of elements, or the element or group of elements may be combined with additional elements to form the component, unless the context indicates otherwise.

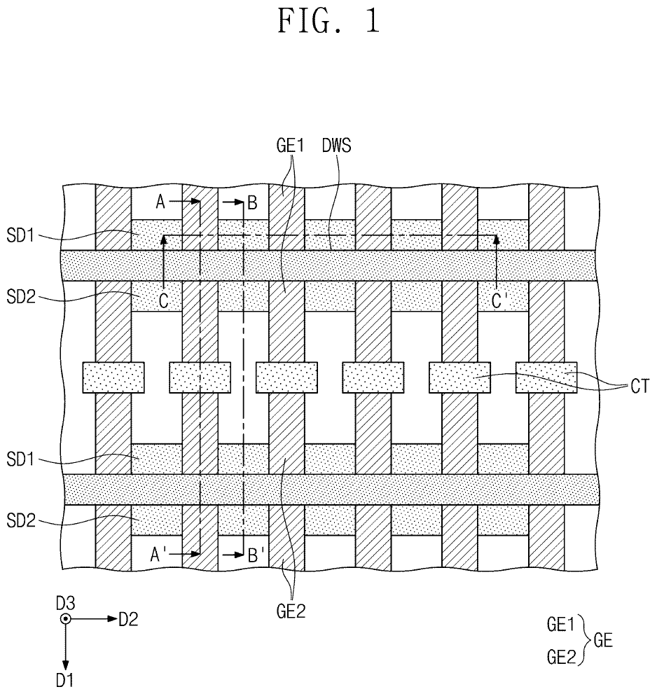

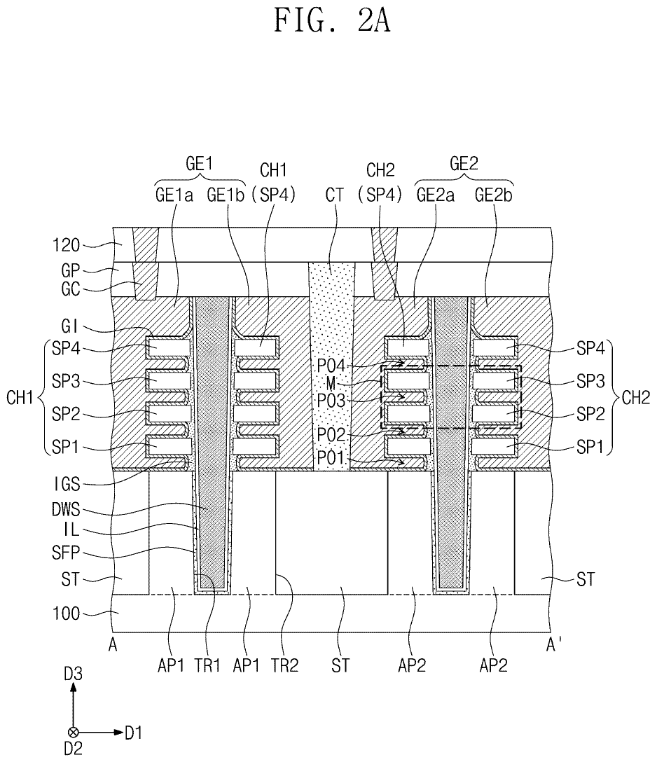

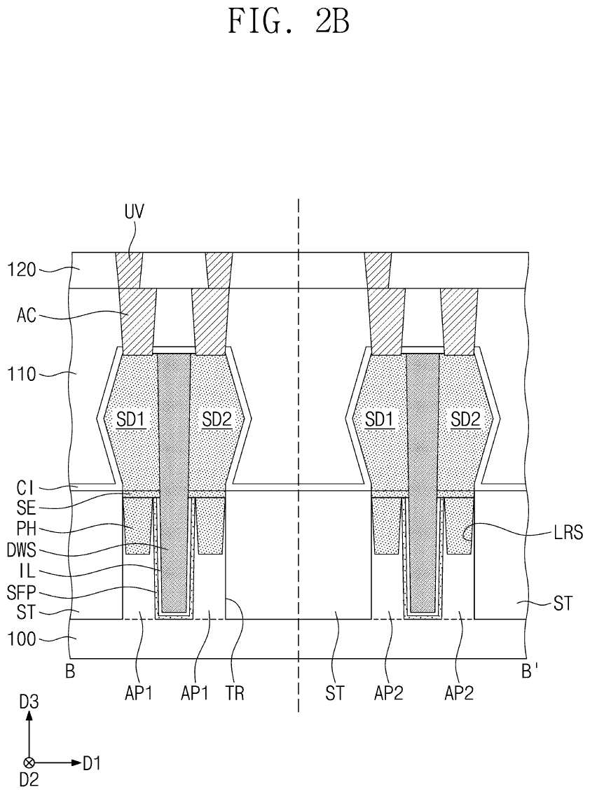

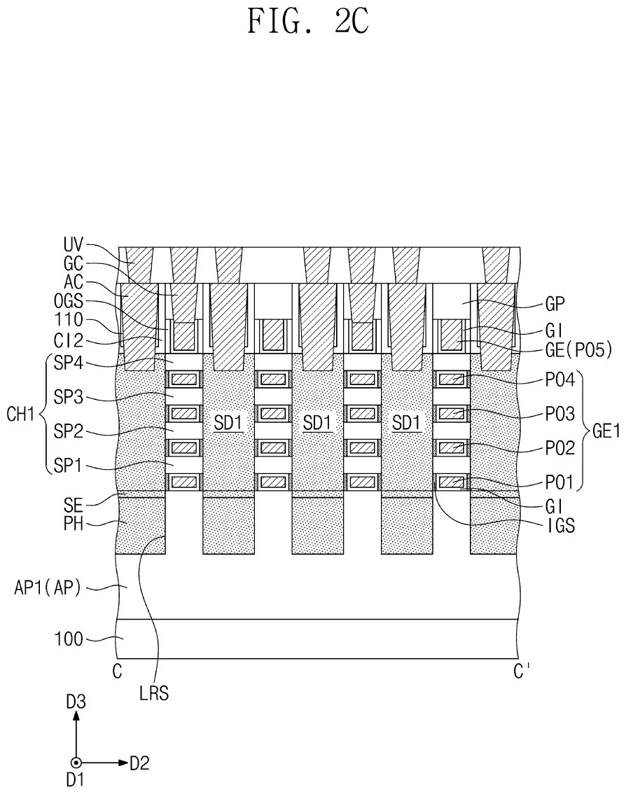

FIG. 1 is a plan view for describing a semiconductor device according to embodiments of the inventive concept. FIGS. 2A to 2C are diagrams, which are cross-sectional views taken along line A-A′, line B-B′, and line C-C′ of FIG. 1, for describing a semiconductor device according to embodiments of the inventive concept.

Referring to FIGS. 1 and 2A to 2C, the semiconductor device may include a substrate 100. A plurality of logic transistors, which may be used to form a logic circuit, may be arranged on the substrate 100. For example, the logic transistors may be field-effect transistors. For example, the substrate 100 may be a base substrate (a bulk crystalline semiconductor substrate, silicon on insulator (SOI), etc.) and may include a crystalline semiconductor material, such as silicon, germanium, silicon-germanium, etc., or a compound semiconductor. In some embodiments, the substrate 100 may be an insulating substrate including a silicon-based insulating layer (or material). In more detail, the substrate 100 may include at least one of silicon oxide, silicon nitride, or silicon oxynitride. In the present disclosure, expressions such as “A or B”, “at least one of A and B”, “at least one of A or B”, “A, B, or C”, “at least one of A, B, and C”, and “at least one of A, B, or C” may each include any one of the items listed together in a corresponding expression among the expressions, or any possible combination thereof.

The substrate 100 may have a shape of a plate expanding along a plane defined by a first direction D1 and a second direction D2. The first direction D1 and the second direction D2 may be parallel to the substrate 100 and may intersect each other. The first direction D1 and the second direction D2 may be referred to as horizontal directions. For example, the first direction D1 and the second direction D2 may be perpendicular to each other.

First active patterns AP1 and second active patterns AP2 may be respectively defined by first and second trenches TR (TR1 and TR2) in the substrate 100. For example, between the first active patterns AP1 and the second active patterns AP2, the second trenches TR2 may be disposed. Between two adjacent first active patterns AP1 (or second active patterns AP2), the first trenches TR1 may be disposed. The first active patterns AP1 and the second active patterns AP2 may be part of the substrate 100 or may be epitaxially grown from the substrate 100. For example, the first active patterns AP1 and the second active patterns AP2 may be formed by etching the substrate 100, and protrude in a third direction D3 perpendicular to the major portion of the upper surface of the substrate 100. For convenience of description, the substrate 100 and the first and second active patterns AP (AP1 and AP2) may be described as components different from each other, but it will be understood that this is also intended to refer to the active patterns AP as being an original part of the substrate 100.

The first active patterns AP1 and the second active patterns AP2 may each extend in the second direction D2. The first active patterns AP1 and the second active patterns AP2 may be spaced apart from each other in the first direction D1 by a device isolation pattern ST to be described later. The first active patterns AP1 or the second active patterns AP2 may be spaced apart from each other in the first direction D1 by an isolation pattern DWS to be described later.

The device isolation pattern ST may be provided on the substrate 100. The device isolation pattern ST may fill the second trenches TR2. In a plan view, the device isolation pattern ST may surround the first and second active patterns AP1 and AP2. An upper surface of the device isolation pattern ST may be coplanar with upper surfaces of the first and second active patterns AP1 and AP2, but the inventive concept is not limited thereto. For example, the device isolation pattern ST may be formed of an insulating material such as silicon oxide.

A first channel pattern CH1 and a second channel pattern CH2 may be provided on each of the first and second active patterns AP1 and AP2. A first set of the first channel patterns CH1 and a second set of the second channel patterns CH2 may be next to each other in the first direction D1. A set of first channel patterns CH1 and set of second channel patterns CH2 may be spaced apart from each other in the first direction D1 by the isolation pattern DWS to be described later. A set of first channel patterns CH1 and another set of first channel patterns CH1 may be spaced apart from each other in the second direction D2. A set of second channel patterns CH2 and another set of second channel patterns CH2 may be spaced apart from each other in the second direction D2.

The set of first channel patterns CH1 and the set of second channel patterns CH2 may each include a first semiconductor pattern SP1, a second semiconductor pattern SP2, a third semiconductor pattern SP3, and a fourth semiconductor pattern SP4. The first to fourth semiconductor patterns SP1, SP2, SP3, and SP4 may be spaced apart from each other in a vertical direction (for example, the third direction D3). For example, the first to fourth semiconductor patterns SP1, SP2, SP3, and SP4 may include crystalline silicon. Each of the first to fourth semiconductor patterns SP1, SP2, SP3, and SP4 may be a nanosheet. According to an embodiment, the number of semiconductor patterns in each set of the first channel patterns CH1 or in each set of the second channel patterns CH1 and CH2 may be variously provided.

First source/drain patterns SD1 and second source/drain patterns SD2 may be provided on each of the first and second active patterns AP1 and AP2. The first source/drain patterns SD1 may be located on both side surfaces of the first channel pattern CH1 and may be electrically connected to and contact the first channel pattern CH1. The second source/drain patterns SD2 may be located on both side surfaces of the second channel pattern CH2 and may be electrically connected to and contact the second channel pattern CH2. Each of the first source/drain patterns SD1 may be located between adjacent first channel patterns CH1, and each of the second source/drain patterns SD2 may be located between adjacent second channel patterns CH2.

The first and second source/drain patterns SD1 and SD2 may include or be impurity regions having a first conductive type (for example, p-type) or a second conductive type (for example, n-type). For example, the first and second source/drain patterns SD1 and SD2 may include or be impurity regions having the same conductive type or impurity regions having different conductive types.

Seed patterns SE may be provided between the first and second source/drain patterns SD1 and SD2 and the first and second active patterns AP1 and AP2. Each of the first and second source/drain patterns SD1 and SD2 may be an epitaxial pattern formed through a selective epitaxial growth (SEG) process using the seed patterns SE as a seed. For example, the first and second source/drain patterns SD1 and SD2 may include one of silicon and silicon-germanium.

A first gate electrode GE1 may be provided on the first active patterns AP1, and a second gate electrode GE2 may be provided on the second active patterns AP2. The first gate electrode GE1 may be located on the first and second channel patterns CH1 and CH2, which are disposed on the first active patterns AP1. The second gate electrode GE2 may be located on the first and second channel patterns CH1 and CH2, which are disposed on the second active patterns AP2.

Each of the first and second gate electrodes GE1 and GE2 may further include a corresponding one of outer electrodes PO5. Accordingly, the first and second gate electrodes GE1 and GE2 may each include first to fourth inner electrodes PO1, PO2, PO3, and PO4 and an outer electrode PO5. The first to third inner electrodes PO1, PO2 and PO3 may be respectively located between the first to fourth semiconductor patterns SP1, SP2, SP3, and SP4. The fourth inner electrode PO4 may be located between the first semiconductor pattern SP1 and a corresponding one of the active patterns AP1 and AP2. The outer electrodes PO5 may be located on the fourth semiconductor pattern SP4 which is an uppermost semiconductor pattern among the first to fourth semiconductor patterns SP1, SP2, SP3, and SP4.

For example, each of the first and second gate electrodes GE1 and GE2 may surround a corresponding set of the first to fourth semiconductor patterns SP1, SP2, SP3, and SP4 of the first channel patterns CH1 or the second channel patterns CH2. For example, the first and second gate electrodes GE1 and GE2 may be parts of a single continuous component such that the interface therebetween is not distinguishable.

In some embodiments, the first gate electrode GE1 and the second gate electrode GE2 may be spaced apart from each other in the first direction D1 by cutting patterns CT as shown in FIG. 1. Though multiple cutting patterns CT have been described in FIG. 1, it should be noted that, in some embodiments, they may constitute a single continuous pattern extending in the second direction D2 in a plan view.

For example, the first and second gate electrodes GE1 and GE2 may include at least one of a metal material (for example, Ti, Mo, W, Cu, Al, Ta, Ru, Ir, Co, etc.), metal nitride (for example, nitride of Ti, Mo, W, Cu, Al, Ta, Ru, Ir, Co, etc.), or impurity-doped polysilicon.

Isolation patterns DWS may be provided on the substrate 100. In a plan view, the isolation patterns DWS may each extend in the second direction D2 and may be spaced apart from each other in the first direction D1. For example, the isolation patterns DWS may include an insulating material such as silicon oxide, silicon nitride, silicon oxynitride, and silicon oxycarbide (SiOC). In addition, the isolation patterns DWS may be a single continuous layer or a composite layer of multiple layers including different insulating materials.

The isolation pattern DWS may be located in the first trench TR1. The isolation pattern DWS may have a shape of a pillar extending in the third direction D3. Each of the isolation pattern DWS may be located between the first active patterns AP1 (or the second active patterns AP2) that are adjacent to each other in the first direction D1. The isolation pattern DWS may be located between two adjacent first active patterns AP1 or two adjacent second active patterns AP2. For example, the isolation pattern DWS may extend between the first active patterns AP1 (or between the second active patterns AP2) adjacent to each other in the first direction D1. Each of the isolation pattern DWS may be located between a first channel pattern CH1 and a second channel pattern CH2 that are adjacent to each other in the first direction D1.

In some embodiments, each isolation pattern DWS may be configured to divide an active pattern AP into two separate vertically extending portions. For example, a first isolation pattern DWS may extend between the first active pattern AP1, and a second isolation pattern may extend between the second active pattern AP2. The first and second isolation patterns DWS may be adjacent to each other in the first direction D1.

The isolation pattern DWS may extend toward a bottom surface of the substrate 100 in a vertical direction. The bottom portion of the isolation pattern DWS may be located at a lower level than upper surfaces of the first and second active patterns AP1 and AP2. The isolation pattern DWS may extend, in the first trench TR1, between the first and second channel patterns CH1 and CH2 adjacent to each other in the first direction D1.

The first and second gate electrodes GE1 and GE2 adjacent to the isolation pattern DWS may surround three surfaces of each of the first to fourth semiconductor patterns SP1, SP2, SP3, and SP4. The isolation pattern DWS may be located between the first and second source/drain patterns SD1 and SD2. The first and second source/drain patterns SD1 and SD2 adjacent to each other in the first direction D1 may be spaced apart from each other by the isolation pattern DWS therebetween.

The first gate electrode GE1 may include a first electrode portion GE1a and a second electrode portion GE1b. The first electrode portion GE1a may be located on the first channel pattern CH1, and the second electrode portion GE1b may be located on the second channel pattern CH2. For example, the first electrode portion GE1a may surround three surfaces of each of the first to fourth semiconductor patterns SP1, SP2, SP3, and SP4 of the first channel pattern CH1, and the second electrode portion GE1b may surround three surfaces of each of the first to fourth semiconductor patterns SP1, SP2, SP3, and SP4 of the second channel pattern CH2.

The first electrode portion GE1a and the second electrode portion GE1b may be spaced apart from each other in the first direction D1 in a plane parallel to the first direction D1 and the second direction D2 by the isolation pattern DWS.

In some embodiments, the first electrode portion GE1a and the second electrode portion GE1b may be spaced apart from each other in the first direction D1 by the isolation pattern DWS, though not shown in the drawings. Accordingly, the first electrode portion GE1a and the second electrode portion GE1b may be electrically insulated from each other. Thus, the first channel pattern CH1 and the second channel pattern CH2 adjacent to the isolation pattern DWS may constitute different logic transistors.

The second gate electrode GE2 may include a first electrode portion GE2a and a second electrode portion GE2b. The first electrode portion GE2a may be located on the first channel pattern CH1, and the second electrode portion GE2b may be located on the second channel pattern CH2. For example, the first electrode portion GE2a may surround three surfaces of each of the first to fourth semiconductor patterns SP1, SP2, SP3, and SP4 of the first channel pattern CH1, and the second electrode portion GE2b may surround three surfaces of each of the first to fourth semiconductor patterns SP1, SP2, SP3, and SP4 of the second channel pattern CH2.

The first electrode portion GE2a and the second electrode portion GE2b may be spaced apart from each other in the first direction D1 in a plane parallel to the first direction D1 and the second direction D2 by the isolation pattern DWS.

In some embodiments, the first electrode portion GE2a and the second electrode portion GE2b may be spaced apart from each other in the first direction D1 by the isolation pattern DWS, though not shown in the drawings. Accordingly, the first electrode portion GE2a and the second electrode portion GE2b may be electrically insulated from each other. Thus, the first channel pattern CH1 and the second channel pattern CH2 adjacent to the isolation pattern DWS may constitute different logic transistors.

A gate insulating layer GI may be provided between the first and second gate electrodes GE1 and GE2 and the first to fourth semiconductor patterns SP1, SP2, SP3, and SP4 of the first and second channel patterns CH1 and CH2. The gate insulating layer GI may cover an upper surface, a lower surface, and one side surface of each of the first to fourth semiconductor patterns SP1, SP2, SP3, and SP4. The gate insulating layer GI may cover both sidewalls of an upper portion of the isolation pattern DWS and an upper surface of the isolation pattern DWS. The gate insulating layer GI may be interposed between an inner gate spacer IGS to be described later and the first gate electrode GE1, and between the inner gate spacer IGS and the second gate electrode GE2. The gate insulating layer GI may extend between the first gate electrode GE1 and the device isolation pattern ST, between the second active pattern AP2 and the device isolation pattern ST, between the first gate electrode GE1 and the first active pattern AP1 and between the first gate electrode GE1 and the second active pattern AP2. The gate insulating layer GI may be also located between the outer electrode PO5 and outer gate spacers OGS to be described later.

The gate insulating layer GI may include silicon oxide, silicon oxynitride, and/or a high-k material. In the present disclosure, the high-k material may be a material having a higher dielectric constant than silicon oxide.

A pair of outer gate spacers OGS may be provided on both side surfaces of the outer electrode PO5 of each of the first and second gate electrodes GE1 and GE2. For example, the outer gate spacers OGS may include at least one of SiON, SiCN, SiOCN, or SiN. In addition, the outer gate spacers OGS may be a single continuous layer or a composite layer of multiple layers having different insulating materials.

Gate capping patterns GP may be provided on the first and second gate electrodes GE1 and GE2. The gate capping patterns GP may cover upper surfaces of the outer electrodes PO5 of the first and second gate electrodes GE1 and GE2. For example, the gate capping patterns GP may include at least one of SiON, SiCN, SiOCN, or SiN.

A first interlayer insulating layer 110 may be provided on the substrate 100. The first interlayer insulating layer 110 may cover the first and second source/drain patterns SD1 and SD2. An upper surface of the first interlayer insulating layer 110 may be substantially coplanar with upper surfaces of the gate capping patterns GP. For example, the first interlayer insulating layer 110 may include an insulating material such as silicon oxide.

A capping insulating layer CI may be provided between the first interlayer insulating layer 110 and the first and second source/drain patterns SD1 and SD2. The capping insulating layer CI may cover surfaces of the first and second source/drain patterns SD1 and SD2 and extend onto the device isolation pattern ST. For example, the capping insulating layer CI may include an insulating material different from that of the first interlayer insulating layer 110. According to an embodiment, the capping insulating layer CI may be a single continuous layer or a composite layer of multiple layers including different insulating materials.

Active contacts AC may be provided in the first interlayer insulating layer 110. The active contacts AC may partially penetrate the first interlayer insulating layer 110 along the third direction D3. The active contacts AC may be connected to corresponding first and second source/drain patterns SD1 and SD2. For example, the active contacts AC may include at least one of a metal material (for example, Ti, Mo, W, Cu, Al, Ta, Ru, Ir, Co, etc.) or metal nitride (for example, nitride of Ti, Mo, W, Cu, Al, Ta, Ru, Ir, Co, etc.). According to an embodiment, an additional isolation pattern including an insulating material may be provided between the active contacts AC. According to an embodiment, a silicide pattern may be provided between the active contacts AC and the first and second source/drain patterns SD1 and SD2.

Gate contacts GC may be provided in the gate capping patterns GP. The gate contacts GC may penetrate the gate capping patterns GP along the third direction D3 to be connected to the first and second gate electrodes GE1 and GE2. For example, the gate contacts GC may include at least one of a metal material (for example, Ti, Mo, W, Cu, Al, Ta, Ru, Ir, Co, etc.) or metal nitride (for example, nitride of Ti, Mo, W, Cu, Al, Ta, Ru, Ir, Co, etc.).

As shown in FIG. 1, cutting patterns CT may each be provided between the first and second gate electrodes GE1 and GE2. The cutting patterns CT may extend in the third direction D3 between adjacent first and second gate electrodes GE1 and GE2. The cutting patterns CT may penetrate an upper portion of the device isolation pattern ST. For example, the cutting patterns CT may each have a vertical length greater than a vertical length of each of the first and second gate electrodes GE1 and GE2. Accordingly, the first and second gate electrodes GE1 and GE2 may be spaced apart from each other in the first direction D1.

A second interlayer insulating layer 120 may be provided on the first interlayer insulating layer 110. The second interlayer insulating layer 120 may cover the first interlayer insulating layer 110, the gate capping patterns GP, the active contacts AC, and the gate contacts GC. The second interlayer insulating layer 120 may include an insulating material that is substantially the same as that of the first interlayer insulating layer 110.

Upper vias UV may be provided in the second interlayer insulating layer 120. The upper vias UV may penetrate the second interlayer insulating layer 120. The upper vias UV may be connected to corresponding active contacts AC and gate contacts GC. For example, the upper vias UV may include a metal material (for example, Ti, Mo, W, Cu, Al, Ta, Ru, Ir, Co, etc.).

According to an embodiment, a metal layer including wiring patterns and via patterns may be provided on the upper vias UV. The wiring patterns and the via patterns of the metal layer may be electrically connected to the upper vias. Adjacent logic transistors may transmit and receive an electrical signal to and from each other through the metal layer. The metal layer may be provided in plurality, and the plurality of metal layers may be stacked along the third direction D3.

For another example, a power delivery network layer may be provided on a lower surface of the substrate 100. For example, the power delivery network layer may include a wiring network for applying a source voltage. Alternatively, the power delivery network layer may include a wiring network for applying a drain voltage. According to an embodiment, the power delivery network layer may include wiring patterns and via patterns. The wiring patterns and the via patterns may be stacked in the third direction D3 and electrically connected to each other.

A back side active contact may be provided between the power delivery network layer and the first and second source/drain patterns SD1 and SD2. The back side active contact may be connected to at least one among the first and second source/drain patterns SD1 and SD2. The back side active contact may be electrically connected to the wiring patterns and the via patterns of the power delivery network layer. Accordingly, at least one among the first and second source/drain patterns SD1 and SD2 may be electrically connected to the power delivery network layer. For example, the back side active contact may include at least one of a metal material (for example, Ti, Mo, W, Cu, Al, Ta, Ru, Ir, Co, etc.) or metal nitride (for example, nitride of Ti, Mo, W, Cu, Al, Ta, Ru, Ir, Co, etc.).

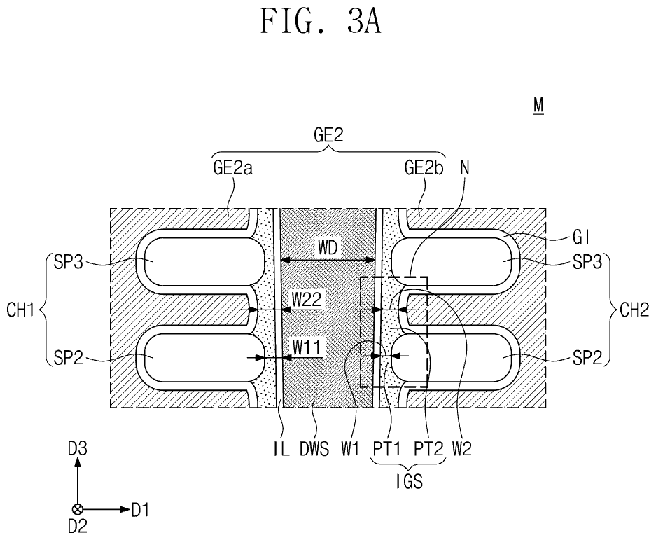

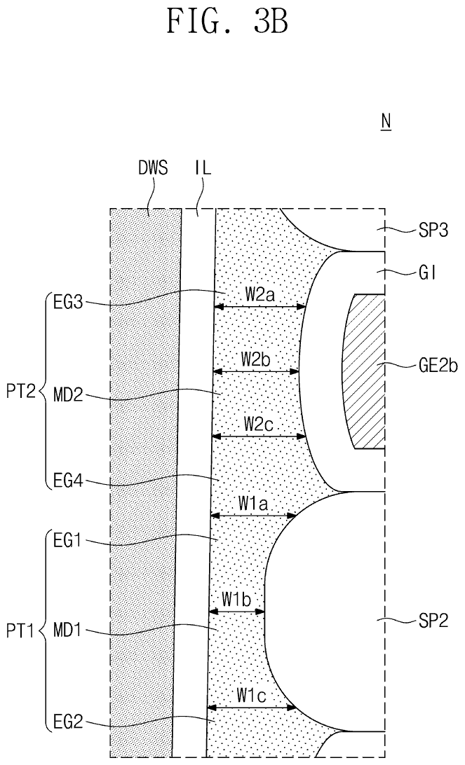

FIG. 3A is an enlarged view of region M of FIG. 2A according to an embodiment of the inventive concept. FIG. 3B is an enlarged view of region N of FIG. 3A according to an embodiment of the inventive concept. The isolation pattern DWS and the inner gate spacer IGS will be described in more detail with reference to FIGS. 2A, 3A, and 3B.

Referring to FIGS. 2A and 3A, the isolation pattern DWS may be spaced apart from at least one among the first to fourth semiconductor patterns SP1, SP2, SP3, and SP4 of the first channel pattern CH1 in the first direction D1. The isolation pattern DWS may be spaced apart from at least one among the first to fourth semiconductor patterns SP1, SP2, SP3, and SP4 of the second channel pattern CH2 in the first direction D1. For example, the isolation pattern DWS may be spaced apart from the first and second semiconductor patterns SP1 and SP2 of the first channel pattern CH1, and may be spaced apart from the third and fourth semiconductor patterns SP3 and SP4 of the first channel pattern CH1. For example, the isolation pattern DWS may be spaced apart from the second and third semiconductor patterns SP2 and SP3 of the second channel pattern CH2 in the first direction D1.

A width WD in the first direction D1 of the isolation pattern DWS may decrease from an upper surface toward a bottom surface of the isolation pattern DWS. An inner insulating layer IL which covers both sidewalls and the bottom surface of the isolation pattern DWS may be provided. The inner insulating layer IL may be provided between the isolation pattern DWS and the first active pattern AP1 and between the isolation pattern DWS and the second active pattern AP2. A thickness of the inner insulating layer IL in the first direction D1 may be smaller than the width WD of the isolation pattern DWS.

The inner gate spacer IGS may be provided on the both sidewalls of the isolation pattern DWS. The inner gate spacer IGS may be provided between the isolation pattern DWS and the first to fourth semiconductor patterns SP1, SP2, SP3, and SP4 of the first channel patterns CH1 and/or between the isolation pattern DWS and the first to fourth semiconductor patterns SP1, SP2, SP3, and SP4 of the second channel patterns CH2. For example, the inner gate spacer IGS may be interposed between the isolation pattern DWS and the second semiconductor pattern SP2 and between the isolation pattern DWS and the third semiconductor pattern SP3.

The inner gate spacer IGS may include silicon oxide and a low-k material. In the present disclosure, the low-k material may be a material having a lower dielectric constant than silicon oxide.

The inner gate spacer IGS may include a first portion PT1 interposed between the isolation pattern DWS and the first to fourth semiconductor patterns SP1, SP2, SP3, and SP4 and a second portion PT2 interposed between the isolation pattern DWS and the second gate electrode GE2. For example, in a plane extending parallel to the substrate 100 (or at the same height relative to the substrate 100), the first portion PT1 may be disposed between the isolation pattern DWS and one of the first to fourth semiconductor patterns SP1, SP2, SP3, and SP4. In a plane extending parallel to the substrate 100 (or at the same height relative to the substrate 100), the second portion PT2 may be disposed between the isolation pattern DWS and the second gate electrode GE2 (and/or between the isolation pattern DWS and the gate insulating layer GI).

In detail, the second portion PT2 may be interposed between the isolation pattern DWS and the first to fourth inner electrodes PO1, PO2, PO3, and PO4 of the second gate electrode GE2. One side of the first portion PT1 may be in contact with the inner insulating layer IL on the isolation pattern DWS, and the other side of the first portion PT1 may be in contact with the second semiconductor pattern SP2. One side of the second portion PT2 may be in contact with the inner insulating layer IL on the isolation pattern DWS, and the other side of the second portion PT2 may be in contact with the gate insulating layer GI which covers the second gate electrode GE2.

The first portion PT1 may have a first width W1 in the first direction D1. The second portion PT2 may have a second width W2 in the first direction D1. The first width W1 may be different from the second width W2. For example, the first width W1 may be greater than the second width W2. A minimum value of the first width W1 may be smaller than a minimum value of the second width W2. Accordingly, a width in the first direction D1 of the inner gate spacer IGS may not be uniform. For example, in the first direction D1, a minimum distance W11 between the semiconductor pattern SP1, SP2, SP3, and SP4 and the isolation pattern DWS may be smaller than a minimum distance W22 between the gate insulating layer GI and the isolation pattern DWS. In some embodiments, the inner insulating layer IL may be a part of the isolation pattern DWS, or the inner insulating layer IL may not be formed. For example, in the first direction D1, a minimum distance W11 between the semiconductor pattern SP1, SP2, SP3, and SP4 and the isolation pattern DWS may be smaller than a minimum distance between the second gate electrode GE2 and the isolation pattern DWS.

Referring to FIG. 3B, the first portion PT1 may include a first inner edge portion EG1, a second inner edge portion EG2, and a first inner center (or middle) portion MD1 between the first inner edge portion EG1 and the second inner edge portion EG2. The first inner edge portion EG1 may be interposed between the isolation pattern DWS and an upper portion of the second semiconductor pattern SP2. The first inner center portion MD1 may be interposed between the isolation pattern DWS and a center (or middle) portion of the second semiconductor pattern SP2. The second inner edge portion EG2 may be interposed between the isolation pattern DWS and a lower portion of the second semiconductor pattern SP2.

The first inner edge portion EG1 may have a first edge width W1a which is a width in the first direction D1. The first inner center portion MD1 may have a first center width W1b which is a width in the first direction D1. The second inner edge portion EG2 may have a second edge width W1c which is a width in the first direction D1. The first edge width W1a and the second edge width W1c may be different from the first center width W1b. For example, the first edge width W1a and the second edge width W1c may be greater than the first center width W1b. The first center width W1b may be a minimum value of the first width W1. The first edge width W1a and the second edge width W1c may be a maximum value of the first width W1.

The first width W1 may have a maximum value at the first inner edge portion EG1, decrease toward the first inner center (or middle) portion MD1, and have a minimum value at the first inner center portion MD1. The first width W1 may increase again from the first inner center portion MD1 toward the second inner edge portion EG2.

The second portion PT2 may include a third inner edge portion EG3, a fourth inner edge portion EG4, and a second inner center (or middle) portion MD2 between the third inner edge portion EG3 and the fourth inner edge portion EG4. The third inner edge portion EG3 may be interposed between the isolation pattern DWS and an upper portion of the inner electrodes (for example, the third inner electrode PO3) of the second gate electrode GE2. The second inner center portion MD2 may be interposed between the isolation pattern DWS and a center (or middle) portion of the inner electrodes PO3 of the second gate electrode GE2. The fourth inner edge portion EG4 may be interposed between the isolation pattern DWS and a lower portion of the inner electrodes PO3 of the second gate electrode GE2.

The third inner edge portion EG3 may have a third edge width W2a which is a width in the first direction D1. The second inner center portion MD2 may have a second center width W2b which is a width in the first direction D1. The fourth inner edge portion EG4 may have a fourth edge width W2c which is a width in the first direction D1. The third edge width W2a and the fourth edge width W2c may be different from the second center width W2b. For example, the third edge width W2a and the fourth edge width W2c may be greater than the second center width W2b. The second center width W2b may be a minimum value of the second width W2. The third edge width W2a and the fourth edge width W2c may be a maximum value of the second width W2.

The second width W2 may have a maximum value at the third inner edge portion EG3, decrease toward the second inner center portion MD2, and have a minimum value at the second inner center portion MD2. The second width W2 may increase again from the second inner center portion MD2 toward the fourth inner edge portion EG4.

In the semiconductor device according to the inventive concept, the isolation pattern DWS and the semiconductor patterns SP1, SP2, SP3, and SP4 may be spaced apart from each other, and the inner gate spacer IGS may be included between the isolation pattern DWS and each of the semiconductor patterns SP1, SP2, SP3, and SP4. In the inner gate spacer IGS, a width of the first portion PT1 interposed between the isolation pattern DWS and a gate electrode may be different from a width of the second portion PT2 interposed between the isolation pattern and a semiconductor pattern. Accordingly, performance deterioration caused by a fixed charge and parasitic capacitance generated between the isolation pattern DWS and the first and second channel patterns CH1 and CH2 may be decreased.

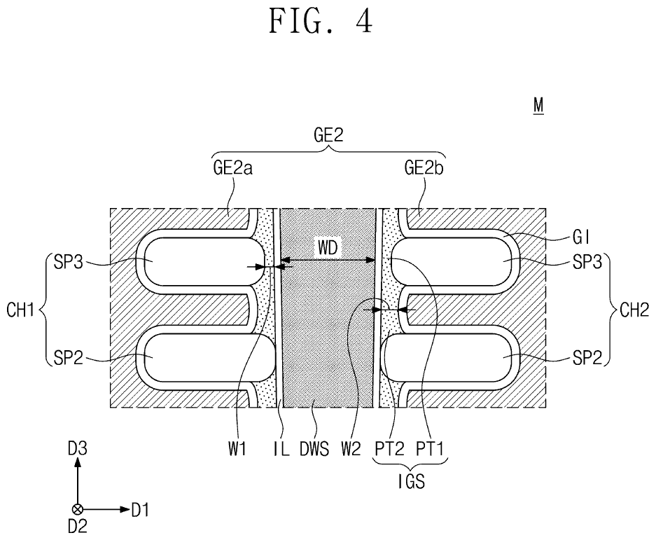

FIGS. 4, 5A, and 6 are enlarged views of region M of FIG. 2A according to other embodiments of the inventive concept. Detailed description of duplicate technical features of those described with reference to drawings described above may not be provided, and a difference therefrom may be described in detail.

Referring to FIG. 4, the isolation pattern DWS and the second semiconductor pattern SP2 may be in contact with each other, and the isolation pattern DWS and the third semiconductor pattern SP3 may be spaced apart from each other. The isolation pattern DWS may be in contact with some of the first to fourth semiconductor patterns SP1, SP2, SP3, and SP4, and spaced apart from the remaining thereof. The inner gate spacer IGS may separate in plurality by the second semiconductor pattern SP2. Here, since a width of the isolation pattern DWS is not uniform, a portion of a sidewall of the isolation pattern DWS may be in contact with a semiconductor pattern, and another portion of the sidewall of the isolation pattern DWS may be spaced apart from a semiconductor pattern.

For example, a width in the first direction D1 of the isolation pattern DWS may decrease from an upper surface toward a bottom surface of the isolation pattern DWS. In this case, the first and second semiconductor patterns SP1 and SP2 (a lower set of the first and second channel patterns CH1 and CH2) may be in contact with the isolation pattern DWS. On the other hand, the third and fourth semiconductor patterns SP3 and SP4 (an upper set of the first and second channel patterns CH1 and CH2) may be spaced apart from the isolation pattern DWS. Accordingly, the description on the non-uniform width (or distance) relationship related to the inner gate spacer IGS may be partially applicable in the embodiment of FIG. 4, because the first and second semiconductor patterns SP1 and SP2 are in contact with the isolation pattern DWS.

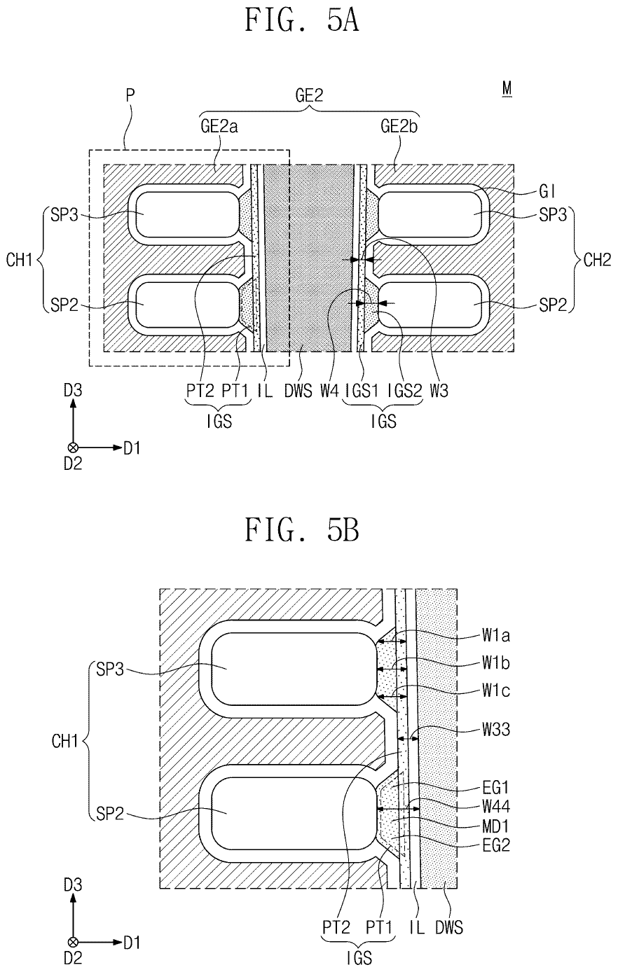

Referring to FIGS. 5A and 5B, the inner gate spacer IGS may include a first inner gate spacer IGS1 and a second inner gate spacer IGS2 on the first inner gate spacer IGS1. The first inner gate spacer IGS1 may be provided on both sidewalls of the isolation pattern DWS. The first inner gate spacer IGS1 may be adjacent to the isolation pattern DWS, as compared to the second inner gate spacer IGS2. The second inner gate spacer IGS2 may be provided between the first inner gate spacer IGS1 and the first to fourth semiconductor patterns SP1, SP2, SP3, and SP4. The second inner gate spacer IGS2 may be adjacent to the first to fourth semiconductor patterns SP1, SP2, SP3, and SP4, as compared to the first inner gate spacer IGS1.

The second inner gate spacer IGS2 may be provided only between the isolation pattern DWS and the first to fourth semiconductor patterns SP1, SP2, SP3, and SP4. The second inner gate spacer IGS2 may not be provided between the isolation pattern DWS and the first and second gate electrodes GE1 and GE2. The first portion PT1 may include the first and second inner gate spacers IGS1 and IGS2, and the second portion PT2 may include only the first inner gate spacer IGS1. Accordingly, a width of the first portion PT1 may be greater than a width of the second portion PT2.

The first inner gate spacer IGS1 may have a third width W3 in the first direction D1. The second inner gate spacer IGS2 may have a fourth width W4 in the first direction D1. A sum of the third width W3 and the fourth width W4 may be a maximum width in the first direction D1 of the inner gate spacer IGS. Referring to FIG. 5B, the first edge width W1a and the second edge width W1c may be smaller than the first center width W1b. The first center width W1b may be a maximum value of the fourth width W4. A width of the first portion PT1 may decrease from the first inner center portion MD1 toward the first and second inner edge portions EG1 and EG2.

For example, in the first direction D1, a maximum distance W44 between the semiconductor pattern SP1, SP2, SP3, and SP4 and the isolation pattern DWS may be greater than a minimum distance W33 between the gate insulating layer GI and the isolation pattern DWS. In some embodiments, the inner insulating layer IL may be a part of the isolation pattern DWS, or the inner insulating layer IL may not be formed.

The first inner center portion MD1 of the first portion PT1 may be in contact with each of the first to fourth semiconductor patterns SP1, SP2, SP3, and SP4. The first and second inner edge portions EG1 and EG2 of the first portion PT1 may be in contact with the gate insulating layer GI in the first direction D1.

The first inner gate spacer IGS1 may include a material different from that of the second inner gate spacer IGS2. The second inner gate spacer IGS2 may include at least one of SiN or SiOCN. A dielectric constant of the first inner gate spacer IGS1 may be smaller than a dielectric constant of the second inner gate spacer IGS2. The second inner gate spacer IGS2 may include a high-k layer. For example, the second inner gate spacer IGS2 may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In some embodiments, the first inner gate spacer IGS1 and the second inner gate spacer IGS2 may include the same material as each other. For example, the first inner gate spacer IGS1 and the second inner gate spacer IGS2 may be a single continuous body.

According to another example of the inventive concept, the inner gate spacer IGS may include dual spacer layers IGS1 and IGS2 including different materials. Accordingly, leakage current between a gate electrode GE and source/drain patterns SD1 and SD2 may be reduced. As a result, electrical characteristics of a semiconductor device may be improved.

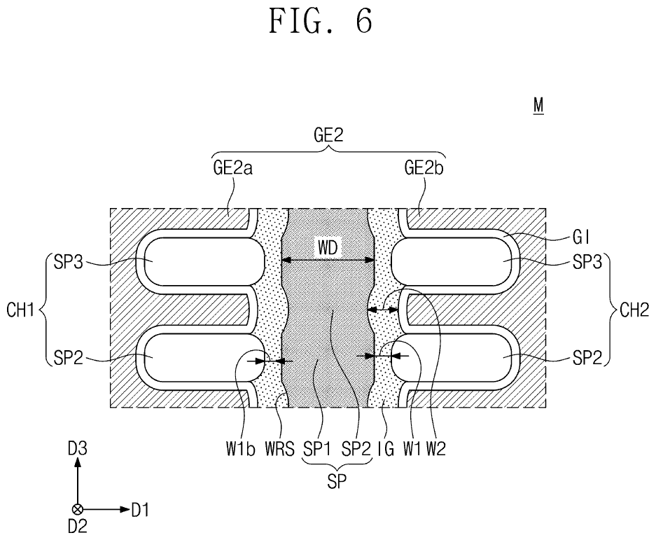

Referring to FIG. 6, both sidewalls of the isolation pattern DWS may have an uneven profile. The both sidewalls of the isolation pattern DWS may include a plurality of isolation recesses WRS recessed toward an inside of the isolation pattern DWS. The inner insulating layer IL on the isolation pattern DWS may be omitted.

A width WD in the first direction D1 of the isolation pattern DWS may not be uniform due to the isolation recess WRS. The isolation pattern DWS may include a first isolation portion SP1 and a second isolation portion SP2. In a plane extending parallel to the substrate 100 (or at the same height relative to the substrate 100), the first isolation portion SP1 may be provided between the first channel pattern CH1 and the second channel pattern CH2. In a plane extending parallel to the substrate 100 (or at the same height relative to the substrate 100, the second isolation portion SP2 may be provided between the first electrode portion GE2a and the second electrode portion GE2b of the second gate electrode GE2. A width of the first isolation portion SP1 may be different from a width of the second isolation portion SP2. For example, the width of the second isolation portion SP2 may be smaller than the width of the first isolation portion SP1. This is because as a sacrificial film SFP is removed in a manufacturing method to be described later, the both sidewalls of the isolation pattern DWS are etched together.

The inner gate spacer IGS which is provided on the both sidewalls of the isolation pattern DWS may fill the isolation recess WRS. The inner gate spacer IGS may include a void. In detail, the void may be formed at a place interposed between the isolation pattern DWS and the first to fourth semiconductor patterns SP1, SP2, SP3, and SP4 in a plane extending parallel to the substrate.

It should be appreciated that an “void” may comprise a gap having air or other gases (e.g., such as those present during manufacturing) or may comprise a gap forming a vacuum therein. The term “air” as discussed herein, may refer to atmospheric air.

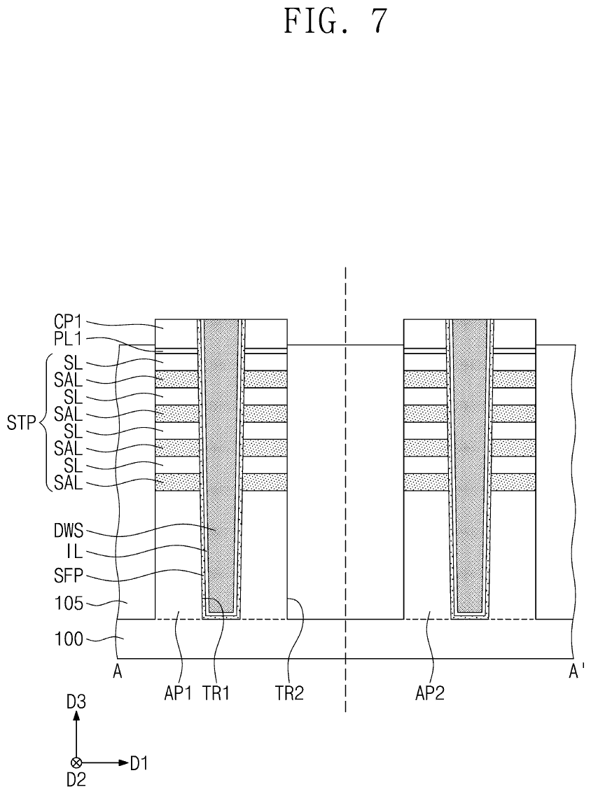

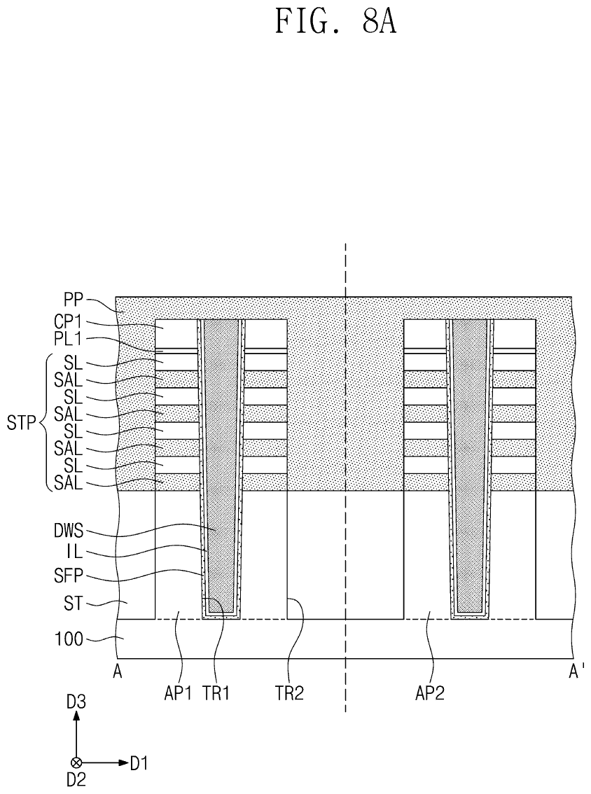

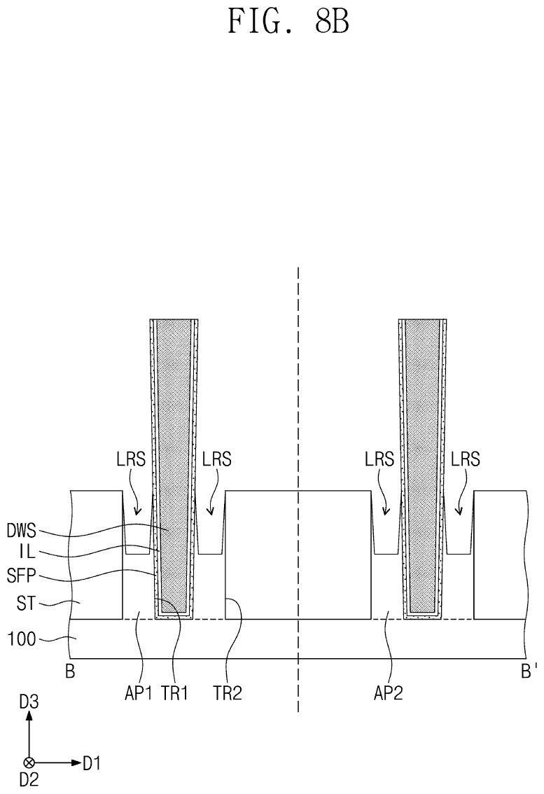

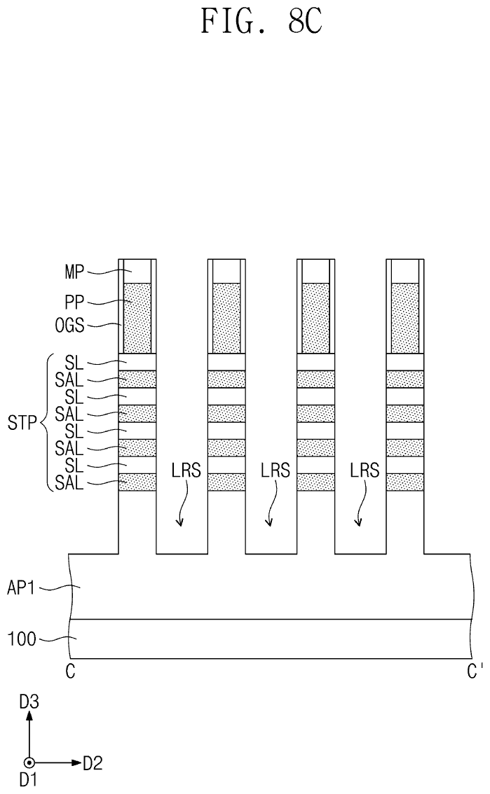

FIGS. 7 to 13C are diagrams for describing a method for manufacturing a semiconductor device according to embodiments of the inventive concept. In detail, FIGS. 7, 8A, 10C, 11A, 12A, and 13A are diagrams taken along line A-A′ of FIG. 1. FIGS. 8B, 9A, 10A, and 13B are diagrams taken along line B-B′ of FIG. 1. FIGS. 8C, 9B, 10B, and 13C are diagrams taken along line C-C′ of FIG. 1.

Referring to FIG. 7, a substrate 100 may be provided. For example, the substrate 100 may be a substrate including silicon, germanium, silicon-germanium, etc., or a compound semiconductor substrate.

Stack patterns STP, a first protective layer PL1, and a first capping pattern CP1 may be sequentially formed on the substrate 100. The stack patterns STP may include semiconductor layers SL and sacrificial layers SAL alternately stacked along the third direction D3. The sacrificial layers SAL may include a material that may have etch selectivity with the semiconductor layers SL. In a process of removing the sacrificial layers SAL to be described later, the semiconductor layers SL may not be removed or may be slightly removed. For example, the semiconductor layers SL may include one of silicon, germanium, and silicon-germanium, and the sacrificial layers SAL may include another of silicon, germanium, and silicon-germanium. The first protective layer PL1 may include an insulating material. The first capping pattern CP1 may include silicon-germanium.

Forming the stack patterns STP, the first protective layer PL1, and the first capping pattern CP1 may include alternately forming the semiconductor layers SL and the sacrificial layers SAL on the substrate 100, forming the first protective layer PL1 and the first capping pattern CP1, and performing a patterning process. An upper portion of the substrate 100 may be removed together due to the patterning process. Accordingly, first and second trenches TR1 and TR2 defining first and second active patterns AP1 and AP2 may be formed. The first and second active patterns AP1 and AP2 may each extend along the second direction D2.

A sacrificial film SFP may be conformally formed on the substrate 100. The sacrificial film SFP may cover sidewalls of each of the stack patterns STP, the first protective layer PL1, and the first capping pattern CP1. The sacrificial film SFP may cover inner sidewalls of each of the first trench TR1 and the second trench TR2. The sacrificial film SFP may be formed to a uniform thickness.

A first insulating layer IL may be conformally formed on the sacrificial film SFP. The first insulating layer IL may include a material having etch selectivity with respect to the sacrificial film SFP. The first insulating layer IL may include an insulating material such as silicon oxide. The first insulating layer IL may be formed to a uniform thickness.

Thereafter, an isolation pattern DWS may be formed in the first trenches TR1. Forming the isolation pattern DWS may include filling the first trenches TR1 with an insulating material, and exposing the first capping pattern CP1 by performing a planarization process on the insulating material. A seam may be formed inside the isolation pattern DWS due to a great aspect ratio of the first trenches TR1. The isolation pattern DWS may include an insulating material such as silicon oxide, silicon nitride, silicon oxynitride, and silicon oxycarbide (SiOC). A device isolation layer 105 may be formed in the second trenches TR2. The device isolation layer 105 may fill the second trenches TR2. Since the second trenches TR2 have a relatively small aspect ratio compared to the first trenches TR1, a seam or a void may not be formed inside the device isolation layer 105.

In some embodiments, after the planarization process, a partial etching process may be performed, for example, to partially remove the sacrificial film disposed above the second trench TR2, thereby providing spaces in which the device isolation layer 105 is to be formed.

Referring to FIGS. 8A, 8B, and 8C, a plurality of sacrificial patterns PP traversing the stack patterns STP may be formed on the stack patterns STP. The sacrificial patterns PP may each be formed having a shape of a line extending in the first direction D1 in a plan view. Forming the sacrificial patterns PP may include forming a sacrificial film on a front surface of the substrate 100, forming hard mask patterns on the sacrificial film, and patterning the sacrificial film by using the hard mask patterns. For example, the sacrificial film may include amorphous silicon and/or polysilicon.

In some embodiments, before the forming of the sacrificial patterns PP, a partial etching process may be performed, for example, to partially remove the device isolation layer 105, thereby providing device isolation patterns ST.

A pair of outer gate spacers OGS may be formed on both side surfaces of each of the sacrificial patterns PP. Forming the outer gate spacers OGS may include forming a spacer layer which covers the sacrificial patterns PP and hard mask patterns HMP, and anisotropically etching the spacer layer. For example, the spacer layer may be a single continuous layer or a composite layer of multiple layers including different insulating materials.

Thereafter, an etching process using the outer gate spacers OGS and the hard mask patterns MP may be performed. A portion of the first and second active patterns AP1 and AP2 and the stack patterns STP may be removed in the etching process. In a plan view, lower recesses LRS may be formed between the sacrificial patterns PP adjacent to each other in the second direction D2 due to the etching process. The stack patterns STP may have a shape extending in the third direction D3 due to the lower recesses LRS.

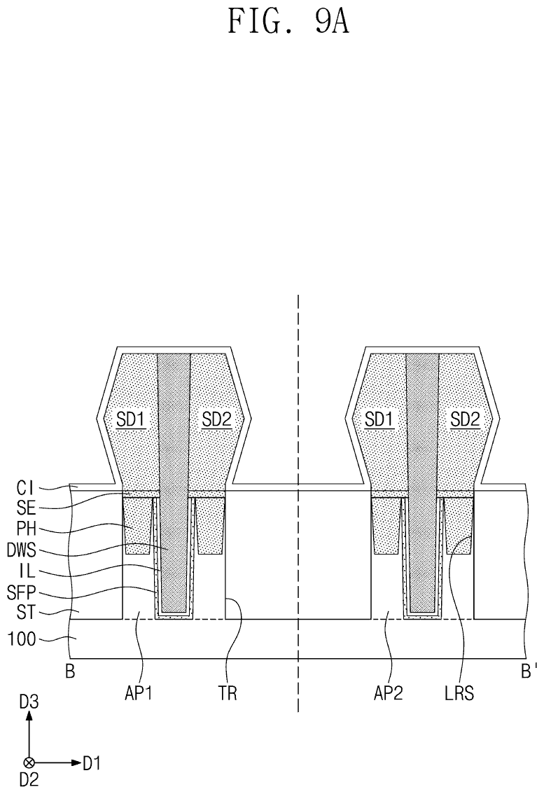

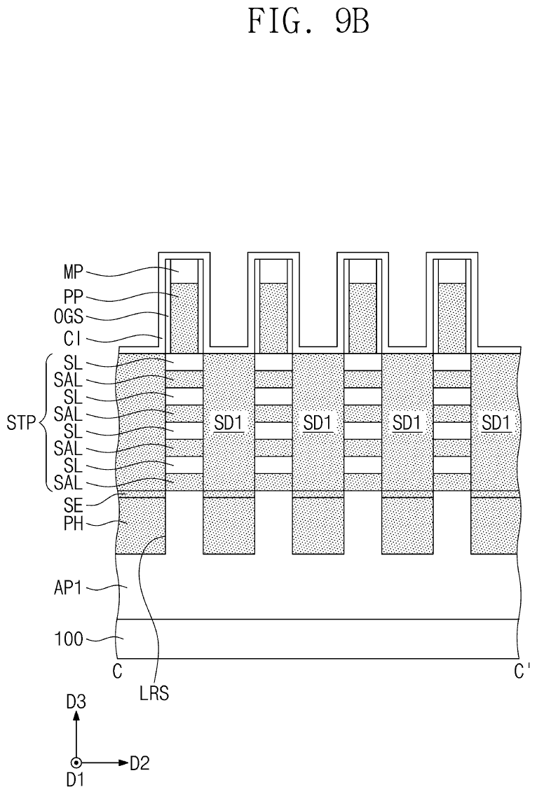

Referring to FIGS. 9A and 9B, sacrificial contact patterns PH may be formed on the first and second active patterns AP1 and AP2 which are exposed by the lower recesses LRS. The sacrificial contact patterns PH may be formed in a form of an array of contacts, to which, for example, a power delivery network layer is electrically connected. The sacrificial contact patterns PH may include a material having etch selectivity with respect to the first and second active patterns AP1 and AP2. For example, the sacrificial contact patterns PH may be formed through an epitaxial growth process and may include silicon-germanium.

Seed patterns SE and first and second source/drain patterns SD1 and SD2 may be sequentially formed on the sacrificial contact patterns PH. The first and second source/drain patterns SD1 and SD2 may be formed through a selective epitaxial growth process in which the seed patterns SE are used as a seed layer. During forming the first and second source/drain patterns SD1 and SD2, an impurity (charge carrier dopants) may be injected into the first and second source/drain patterns SD1 and SD2 in-situ. Alternatively, an impurity may be injected after the first and second source/drain patterns SD1 and SD2 are formed.

In some embodiments, the first and second source/drain patterns SD1 and SD2 may be formed through two different selective epitaxial growth processed, thereby allowing the doping types of SD1 and SD2 to be easily adjusted.

Thereafter, a capping insulating layer CI may be formed on the front surface of the substrate 100. The capping insulating layer CI may cover the hard mask patterns MP, the first and second source/drain patterns SD1 and SD2, and a device isolation pattern. The capping insulating layer CI may have a uniform thickness.

A portion of the inner insulating layer IL on a side surface of the isolation pattern DWS, adjacent to the first and second source/drain patterns SD1 and SD2 may be removed before the first and second source/drain patterns SD1 and SD2 are formed.

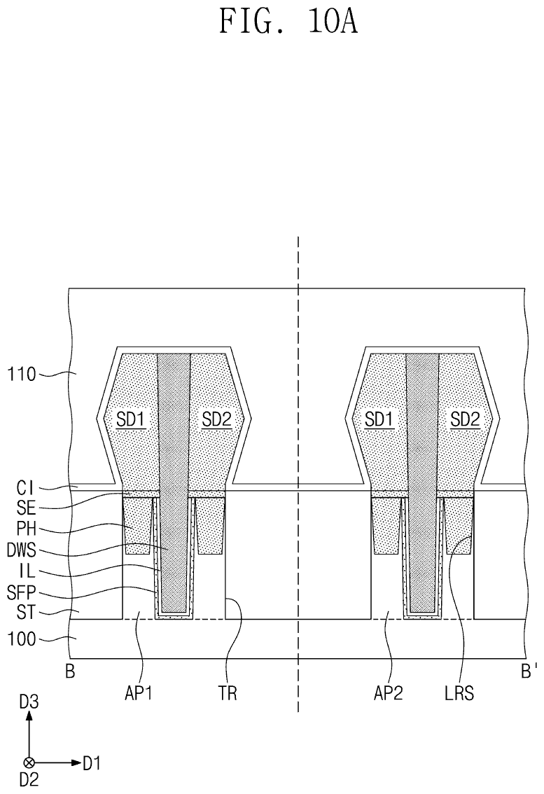

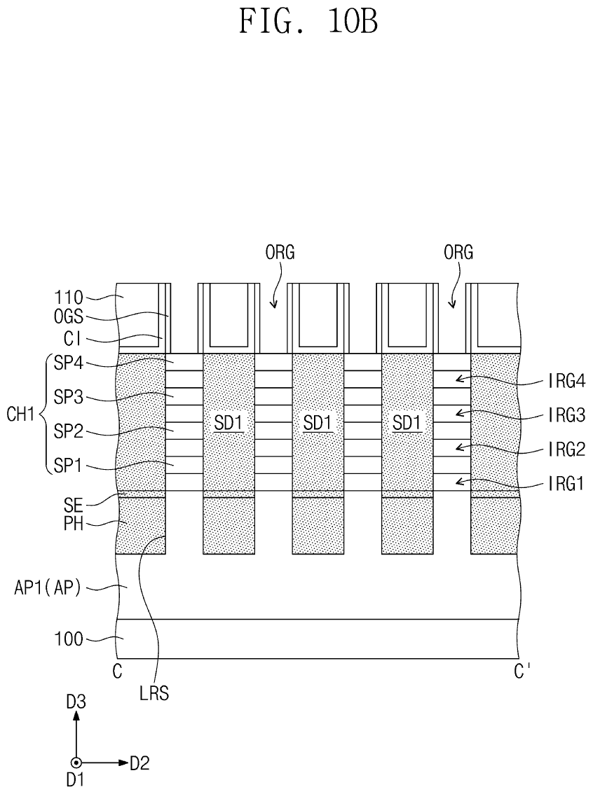

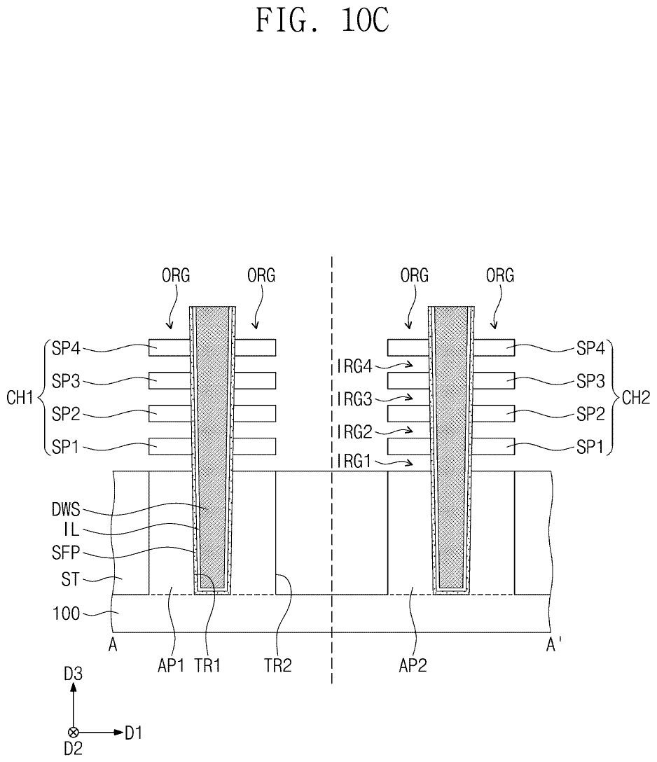

Referring to FIGS. 10A, 10B, and 10C, a first interlayer insulating layer 110 may be formed on the first and second source/drain patterns SD1 and SD2. The first interlayer insulating layer 110 may cover the capping insulating layer CI. Thereafter, a planarization process may be performed on the first interlayer insulating layer 110 until upper surfaces of the sacrificial patterns PP are exposed. The hard mask patterns MP on the sacrificial patterns PP may be removed together in the planarization process. Accordingly, an upper surface of the first interlayer insulating layer 110 may be coplanar with the upper surfaces of the sacrificial patterns PP and upper surfaces of the outer gate spacers OGS.

The exposed sacrificial patterns PP may be selectively removed. Removing the sacrificial patterns PP may include a wet etching process using an etchant which selectively removes polysilicon. An outer region ORG may be formed by removing the sacrificial patterns PP. The stack patterns STP may be exposed to the outside due to the outer region ORG.

The sacrificial layers SAL of the stack patterns STP exposed through the outer region ORG may be selectively removed. An inner region IRG may be formed by selectively removing the sacrificial layers SAL. Only the sacrificial layers SAL may be removed and the semiconductor layers SL may remain as they are in an etching process of selectively removing the sacrificial layers SAL. The etching process of removing the sacrificial layers SAL may have high etch rate with respect to silicon-germanium. Accordingly, a channel pattern of a logic transistor may be formed from the semiconductor layers SL. For example, first and second channel patterns CH1 and CH2 including first to fourth semiconductor patterns SP1, SP2, SP3, and SP4 may be formed.

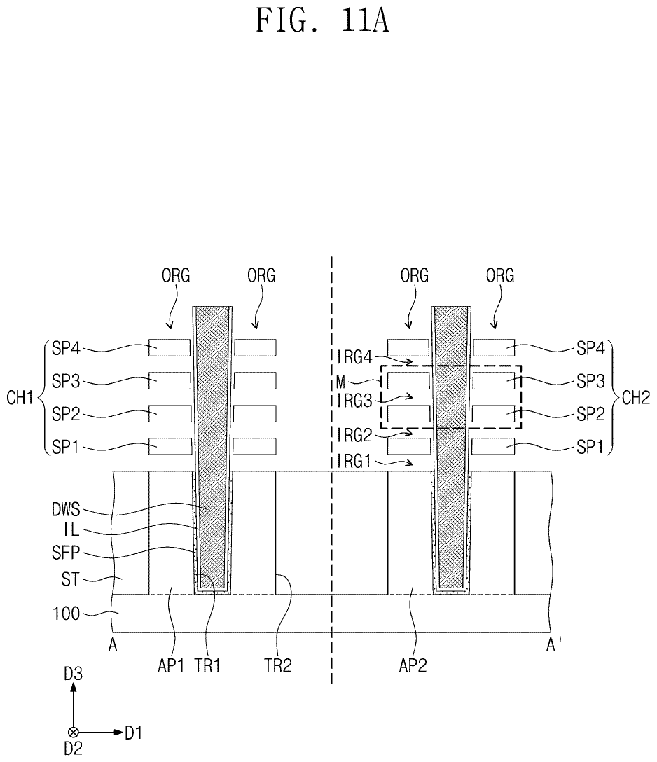

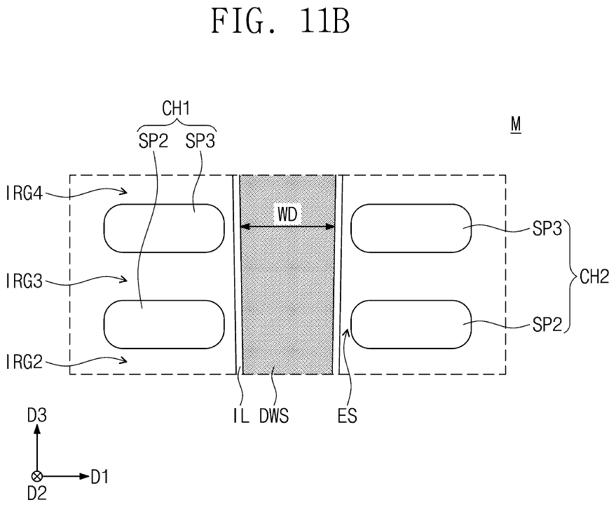

Referring to FIGS. 11A and 11B, the sacrificial film SFP on the side surface of the isolation pattern DWS may be exposed through the inner region IRG. A portion of the sacrificial film SFP exposed through the inner region IRG may be selectively removed, but the sacrificial film SFP between the first and second active patterns AP1 and AP2 and the isolation pattern DWS may remain as it is. The inner insulating layer IL on the side surface of the isolation pattern DWS may not be removed and may remain as it is. Accordingly, the first to fourth semiconductor patterns SP1, SP2, SP3, and SP4 of the first and second channel patterns CH1 and CH2 may be spaced apart from the isolation pattern DWS. A separation space ES, which is an empty space, may be formed between the isolation pattern DWS and the first to fourth semiconductor patterns SP1, SP2, SP3, and SP4 of the first and second channel patterns CH1 and CH2.

For another example, the separation space ES may be formed in a process of removing the sacrificial layers SAL described with reference to FIGS. 10A and 10B. In detail, a portion of the sacrificial film SFP exposed through the inner region IRG, which is formed by removing the sacrificial layers SAL, may be removed together with the sacrificial layers SAL. For example, after the sacrificial layers SAL is removed, the removing process may be continuously performed to further remove the sacrificial film SFP.

For another example, the separation space ES may be formed before the sacrificial layer SAL is removed. In detail, before the sacrificial pattern PP is removed in the process step described with reference to FIGS. 10A and 10B, the sacrificial film SFP may be selectively removed by exposing an upper surface of the isolation pattern DWS. In this case, only an upper portion of the sacrificial film SFP may be removed, and the sacrificial film SFP between the isolation pattern DWS and the first and second semiconductor patterns SP1 and SP2 may remain as it is.

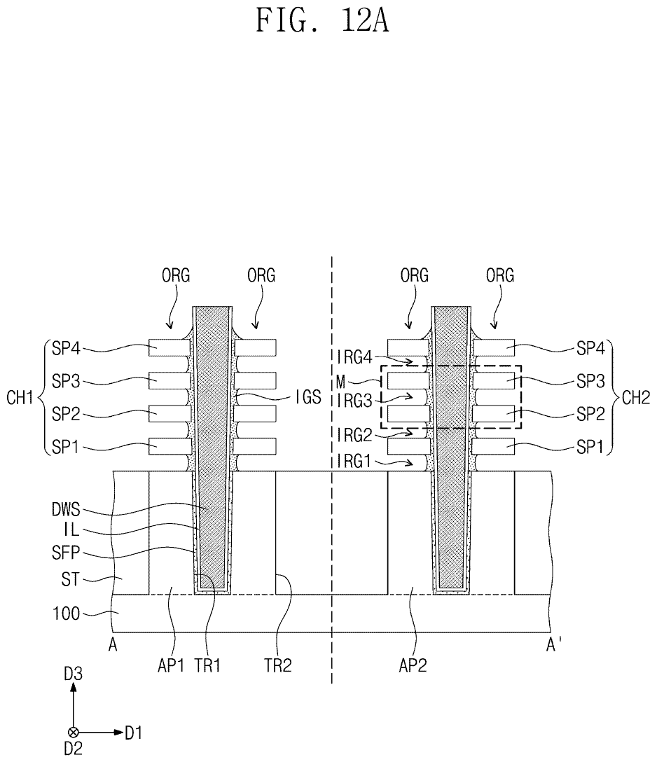

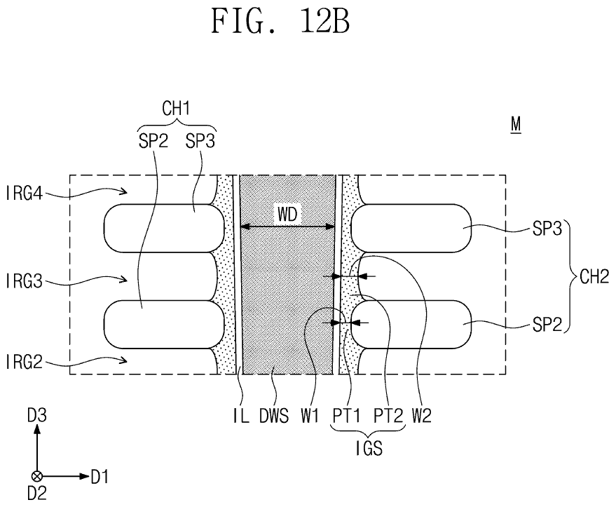

Referring to FIGS. 12A and 12B, an inner gate spacer IGS may be formed in the separation space ES. The inner gate spacer IGS may be formed on the side surface of the isolation pattern DWS. The inner gate spacer IGS may be located between the isolation pattern DWS and the first to fourth semiconductor patterns SP1, SP2, SP3, and SP4 of the first and second channel patterns CH1 and CH2.

The inner gate spacer IGS may reduce leakage current that is generated from the first to fourth semiconductor patterns SP1, SP2, SP3, and SP4. Thus, electrical characteristics of the semiconductor device may be improved. The leakage current that is generated from the first to fourth semiconductor patterns SP1, SP2, SP3, and SP4 may be reduced by interposing the inner gate spacer IGS between the isolation pattern DWS and the first to fourth semiconductor patterns SP1, SP2, SP3, and SP4. Thus, electrical characteristics of the semiconductor device may be improved.

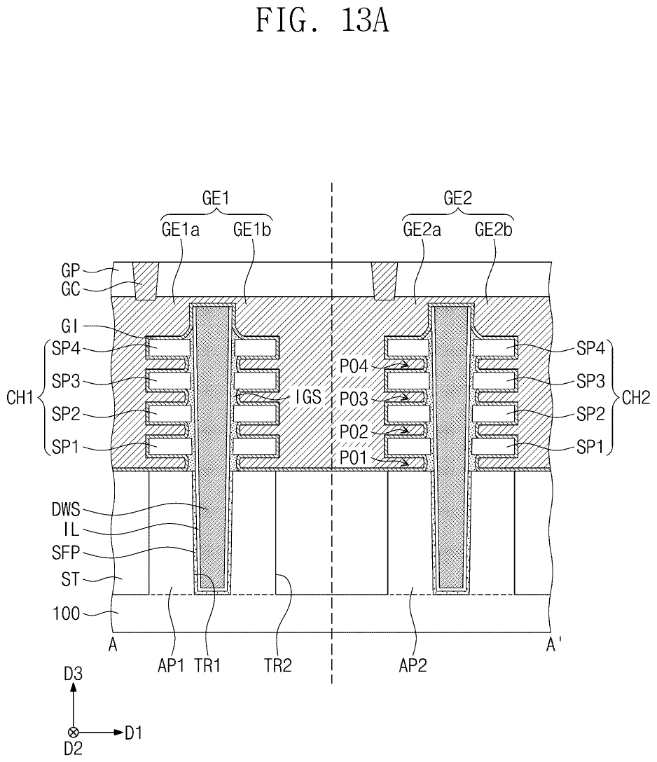

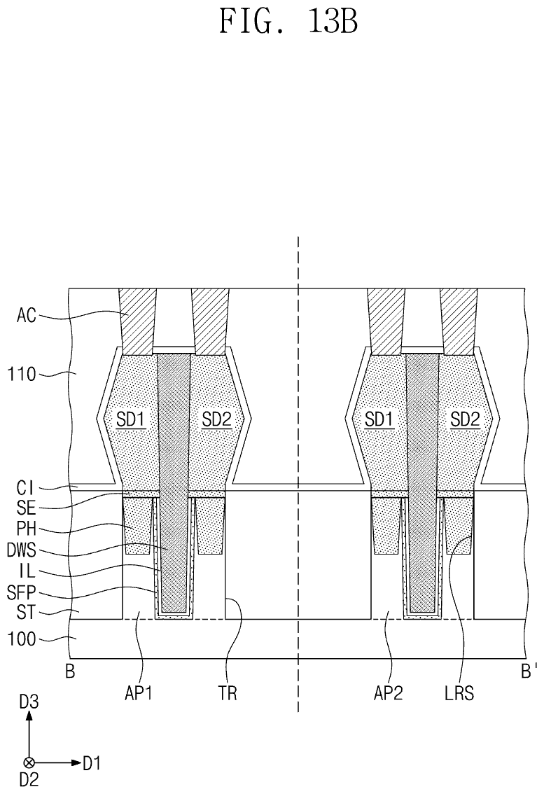

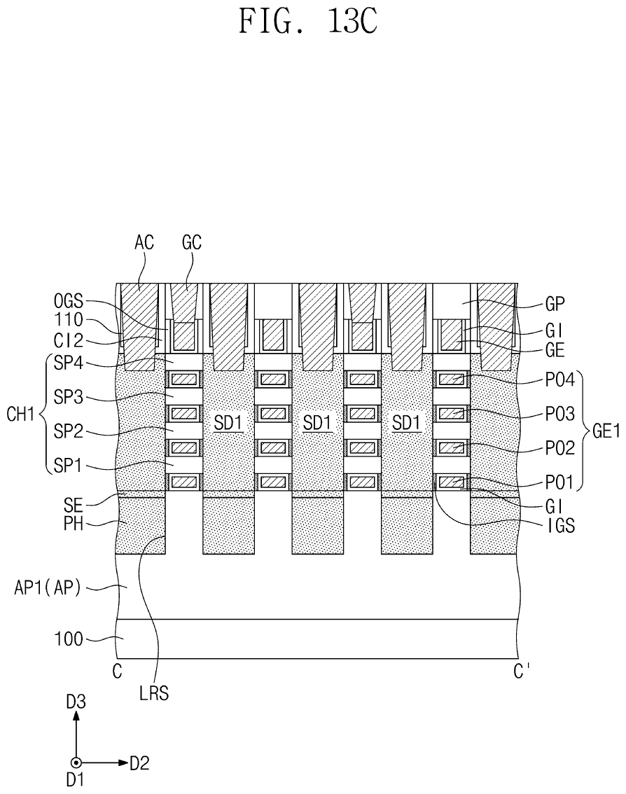

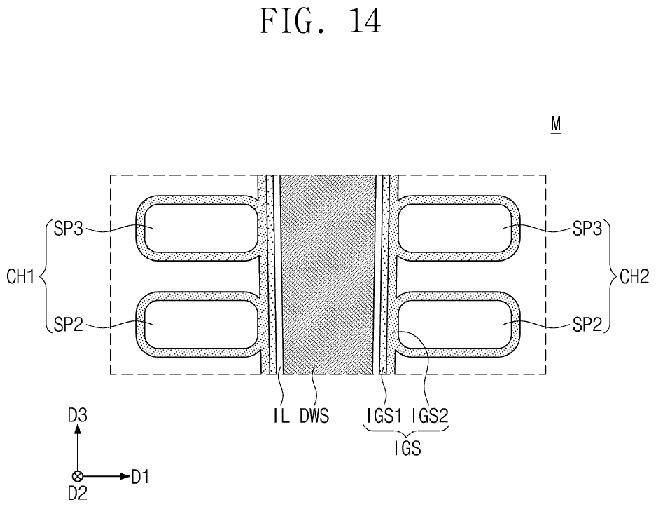

Referring to FIGS. 13A, 13B, and 13C, a gate insulating layer GI may be formed to a uniform thickness in the inner region IRG and the outer region ORG after inner gate spacers IGS are formed. The gate insulating layer GI may cover the first to fourth semiconductor patterns SP1, SP2, SP3, and SP4 of the first and second channel patterns CH1 and CH2, the isolation pattern DWS, and a device isolation pattern ST.

First and second gate electrodes GE1 and GE2 may be formed on the gate insulating layer GI. Forming the first and second gate electrodes GE1 and GE2 may include forming inner electrodes PO1, PO2, PO3, and PO4 between the first to fourth semiconductor patterns SP1, SP2, SP3, and SP4 and forming an outer electrode PO5 in the outer region ORG.

Gate capping patterns GP may be formed on the first and second gate electrodes GE1 and GE2. A planarization process may be performed on the gate capping patterns GP so that upper surfaces of the gate capping patterns GP are coplanar with an upper surface of the first interlayer insulating layer 110.

Thereafter, though not shown in the drawings, cutting patterns penetrating the first and second gate electrodes GE1 and GE2 may be formed. The cutting patterns may extend from the gate capping patterns GP to the device isolation pattern ST. The first and second gate electrodes GE1 and GE2 may be spaced apart from each other in the first direction D1 by the cutting patterns.

Active contacts AC may be formed in the first interlayer insulating layer 110. Each of the active contacts AC may penetrate the first interlayer insulating layer 110 to be connected to at least any one among the first and second source/drain patterns SD1 and SD2.

Gate contacts GC may be formed in the gate capping patterns GP. The gate contacts GC may penetrate the gate capping patterns GP to be connected to the first and second gate electrodes GE1 and GE2.

Referring back to FIGS. 2A, 2B, 2C, and 2D, a second interlayer insulating layer 120 may be formed on the first interlayer insulating layer 110. Upper vias UV may be formed in the second interlayer insulating layer 120. The upper vias UV may penetrate the second interlayer insulating layer 120 to be connected to the active contacts AC and the gate contacts GC.

FIG. 14 is a diagram for describing a method for manufacturing a semiconductor device according to FIG. 5A. FIG. 14 may be a diagram for describing a manufacturing process step that is performed after the process step described with reference to FIGS. 11A and 11B.

Referring to FIG. 14, a first inner gate spacer IGS1 may be conformally formed on a side surface of the isolation pattern DWS. The first inner gate spacer IGS1 may not fully fill the separation space ES of FIG. 11B. A second inner gate spacer IGS2 may be conformally formed on the first inner gate spacer IGS1. The second inner gate spacer IGS2 may be provided in the remaining space of the separation space ES. The second inner gate spacer IGS2 may surround the first to fourth semiconductor patterns SP1, SP2, SP3, and SP4.

Referring back to FIG. 5A, a portion of the second inner gate spacer IGS2 exposed through the inner region IRG and the outer region ORG may be selectively removed through an etching process. The other portion of the second inner gate spacer IGS2 interposed between the isolation pattern DWS and the first to fourth semiconductor patterns SP1, SP2, SP3, and SP4 may remain as it is. Widths of edge portions of the second inner gate spacer IGS2 may be reduced due to the etching process such that the second inner gate spacer IGS2 has inclined edges with respect to the sidewall of the isolation pattern DWS.

In a semiconductor device according to the inventive concept, an isolation pattern and semiconductor patterns may be spaced apart from each other, and an inner gate spacer may be included between the isolation pattern and first semiconductor patterns. Accordingly, performance deterioration caused by a fixed charge and parasitic capacitance generated between the isolation pattern and a channel pattern may be reduced.

In the inner gate spacer of the semiconductor device according to the inventive concept, a width of a portion between the isolation pattern and a gate electrode may be different from a width of a portion between the isolation pattern and the semiconductor pattern. In addition, the inner gate spacer may include dual spacer layers including different materials. Accordingly, leakage current between the gate electrode and a source/drain pattern may be reduced.

In the above, embodiments of the inventive concept have been described with reference to the accompanying drawings, but those of ordinary skill in the art may understand that the inventive concept can be carried out in other specific forms without departing from the technical concept or essential features of the invention. Therefore, the above embodiments should be considered illustrative and should not be construed as limiting.

What is claimed is:

1. A semiconductor device comprising:
active patterns on a substrate;
a first set of semiconductor patterns and a second set of semiconductor patterns spaced apart from each other in a first direction on the active patterns, the first set of semiconductor patterns including a first semiconductor pattern and a second semiconductor pattern vertically spaced apart from each other in a second direction perpendicular to the first direction;
an isolation pattern between the first set of semiconductor patterns and the second set of semiconductor patterns;
a first gate electrode on the first set of semiconductor patterns; and
an inner gate spacer on a sidewall of the isolation pattern,
wherein the isolation pattern and the first semiconductor pattern are spaced apart from each other in the first direction,
the inner gate spacer is interposed between the isolation pattern and the first semiconductor pattern, and
in the first direction, the minimum distance between the first semiconductor pattern and the isolation pattern is different from the minimum distance between the first gate electrode and the isolation pattern.

2. The semiconductor device of claim 1,
wherein the inner gate spacer comprises:
a first portion between the isolation pattern and the first semiconductor pattern in a plane extending parallel to the substrate; and
a second portion between the isolation pattern and the first gate electrode in a plane extending parallel to the substrate,
wherein a width of the first portion is different from a width of the second portion.

3. The semiconductor device of claim 2,
wherein the first portion further comprises:
a first inner edge portion between the isolation pattern and an upper portion of the first semiconductor pattern in a plane extending parallel to the substrate;
a first inner middle portion between the isolation pattern and a middle portion of the first semiconductor pattern in a plane extending parallel to the substrate; and
a second inner edge portion between the isolation pattern and a lower portion of the first semiconductor pattern in a plane extending parallel to the substrate, and
wherein, in the first direction, a width of the first inner edge portion and a width of the second inner edge portion are greater than a width of the first inner middle portion.

4. The semiconductor device of claim 2,
wherein the first portion further comprises:
a first inner edge portion between the isolation pattern and an upper portion of the first semiconductor pattern;
a first inner middle portion between the isolation pattern and a middle portion of the first semiconductor pattern; and
a second inner edge portion between the isolation pattern and a lower portion of the first semiconductor pattern, and
wherein, in the first direction, a width of the first inner edge portion and a width of the second inner edge portion are smaller than a width of the first inner middle portion.

5. The semiconductor device of claim 3, wherein the first inner middle portion is in contact with the first semiconductor pattern, and
the first inner edge portion and the second inner edge portion are spaced apart from the first semiconductor pattern.

6. The semiconductor device of claim 1, further comprising a second gate electrode on the second set of semiconductor patterns,
wherein the isolation pattern includes:
a first isolation portion between the first set of semiconductor patterns and the second set of semiconductor patterns in a plane extending parallel to the substrate; and
a second isolation portion between the first gate electrode and the second gate electrode in a plane extending parallel to the substrate, and
wherein, in the first direction, a width of the second isolation portion is smaller than a width of the first isolation portion.

7. The semiconductor device of claim 1, wherein the inner gate spacer comprises a first inner gate spacer and a second inner gate spacer on the first inner gate spacer, and
the first inner gate spacer comprises a material different from that of the second inner gate spacer.

8. The semiconductor device of claim 7, wherein the first inner gate spacer is adjacent to the isolation pattern,
the second inner gate spacer is adjacent to the first semiconductor pattern, and
the first inner gate spacer is positioned nearer to the isolation pattern than to the first semiconductor pattern.

9. The semiconductor device of claim 7, wherein a dielectric constant of the second inner gate spacer is greater than a dielectric constant of the first inner gate spacer.

10. The semiconductor device of claim 1, wherein the second semiconductor pattern is in contact with the isolation pattern.

11. The semiconductor device of claim 1, further comprising a void between the isolation pattern and the first semiconductor pattern in a plane extending parallel to the substrate.

12. A semiconductor device comprising:
active patterns on a substrate;
a first set of semiconductor patterns and a second set of semiconductor patterns spaced apart from each other on the active patterns, the first set of semiconductor patterns including a first semiconductor pattern and a second semiconductor pattern vertically spaced apart from each other;
an isolation pattern between the first set of semiconductor patterns and the second set of semiconductor patterns;
a first gate electrode on the first set of semiconductor patterns; and
an inner gate spacer on a sidewall of the isolation pattern,
wherein the inner gate spacer includes:
a first portion between the isolation pattern and the first semiconductor pattern in a plane extending parallel to the substrate, and
a second portion between the isolation pattern and the first gate electrode in a plane extending parallel to the substrate, and
wherein, in a direction extending parallel to the substrate, a width of the first portion is different from a width of the second portion.

13. The semiconductor device of claim 12, further comprising a second gate electrode on the second set of semiconductor patterns,
wherein the isolation pattern includes:
a first isolation portion between the first set of semiconductor patterns and the second set of semiconductor patterns in a plane extending parallel to the substrate; and
a second isolation portion between the first gate electrode and the second gate electrode in a plane extending parallel to the substrate, and
in a direction extending parallel to the substrate, a width of the second isolation portion is smaller than a width of the first isolation portion.

14. The semiconductor device of claim 12, wherein the first portion comprises a first inner gate spacer and a second inner gate spacer on the first inner gate spacer, and
the first inner gate spacer comprises a material different from that of the second inner gate spacer.

15. The semiconductor device of claim 14, wherein a dielectric constant of the second inner gate spacer is greater than a dielectric constant of the first inner gate spacer.

16. A semiconductor device comprising:
a substrate including active patterns;
a device isolation layer defining the active patterns;
a first set of semiconductor patterns and a second set of semiconductor patterns spaced apart from each other in a first direction on the active patterns, the first set of semiconductor patterns including a first semiconductor pattern and a second semiconductor pattern vertically spaced apart from each other in a second direction perpendicular to the first direction;
source/drain patterns connected to the first and second set of semiconductor patterns;
an isolation pattern between the first set of semiconductor patterns and the second set of semiconductor patterns;
a first gate electrode surrounding the first and second semiconductor patterns with respect to a vertical cross sectional view the first set of semiconductor patterns;
a second gate electrode on the second set of semiconductor patterns;
a gate insulating layer interposed between the first and second gate electrodes and each of the first and second set of semiconductor patterns;
an inner gate spacer on a sidewall of the isolation pattern;
a gate spacer on a sidewall of the first and second gate electrodes;
gate capping patterns on upper surfaces of the first and second gate electrodes;
an interlayer insulating layer covering the source/drain pattern and the gate capping patterns;
an active contact penetrating the interlayer insulating layer and electrically connected to one of the source/drain patterns;
a gate contact penetrating the gate capping pattern and the interlayer insulating layer and electrically connected to one of the first and second gate electrodes; and
a first metal layer on the interlayer insulating layer, the first metal layer including first and second lines electrically connected to the active contact and the gate contact,
wherein the isolation pattern and the first semiconductor pattern are spaced apart from each other in the first direction,
wherein the inner gate spacer further includes
a first inner edge portion between the isolation pattern and an upper portion of the first semiconductor pattern in a plane extending parallel to the substrate,
a first inner middle portion between the isolation pattern and a middle portion of the first semiconductor pattern in a plane extending parallel to the substrate, and
a second inner edge portion between the isolation pattern and a lower portion of the first semiconductor pattern in a plane extending parallel to the substrate, and
wherein, in the first direction, a width of the first inner edge portion is different from a width of the first inner middle portion.

17. The semiconductor device of claim 16, wherein a width of the inner gate spacer in the first direction decreases from the first inner edge portion toward the first inner middle portion, and increases from the first inner middle portion toward the second inner edge portion.

18. The semiconductor device of claim 16, wherein a width of the inner gate spacer in the first direction increases from the first inner edge portion toward the first inner middle portion, and decreases from the first inner middle portion toward the second inner edge portion.

19. The semiconductor device of claim 16, wherein the first inner middle portion is in contact with the first semiconductor pattern, and
the first inner edge portion and the second inner edge portion are spaced apart from the first semiconductor pattern.

20. The semiconductor device of claim 16,
wherein the isolation pattern comprises:
a first isolation portion between the first set of semiconductor patterns and the second set of semiconductor patterns in a plane extending parallel to the substrate; and
a second isolation portion between the first gate electrode and the second gate electrode in a plane extending parallel to the substrate, and
wherein, in the first direction, a width of the second isolation portion is smaller than a width of the first isolation portion.
